(19) United States
(12) Patent Application Publication
(10) Pub. No.: US 2011/0011443 A1
(43) Pub. Date: Jan. 20, 2011

(54) SOLAR BATTERY MODULE AND MANUFACTURING METHOD THEREOF

(75) Inventors: Shigeo Yata, Kobe-shi (JP); Kazushige Kaneko, Gifu-shi (JP); Sho Takahashi, Anpachi-gun (JP)

Correspondence Address: DITTHAVONG MORI & STEINER, P.C., 918 Prince Street, Alexandria, VA, 22314, US

(73) Assignee: SANYO ELECTRIC CO., LTD., Moriguchi-shi (JP)

(21) Appl. No.: 12/750,212

(22) Filed: Mar. 30, 2010

(30) Foreign Application Priority Data
Jul. 17, 2009 (JP) 2009-169376
Jul. 17, 2009 (JP) 2009-169377
Jul. 17, 2009 (JP) 2009-169378

(51) Int. Cl. H01L 31/0232; H01L 31/18

(52) U.S. Cl. 136/246; 438/72; 257/E31.127

(57) ABSTRACT

A solar battery module is provided comprising a light-transmissive substrate, a solar battery formed over a first surface of the light-transmissive substrate, and a first reflective section which is made of the same material as an electrode forming a part of the solar battery, which is provided over a second surface of the light-transmissive substrate, and which reflects light from the side of the substrate.

### CROSS-REFERENCE TO RELATED APPLICATIONS

The entire disclosure of Japanese Patent Application Nos. 2009-169376, 2009-169377, and 2009-169378 filed on Jul. 17, 2009, including specification, claims, drawings, and abstract is incorporated herein by reference in its entirety.

### BACKGROUND

1. Technical Field

The present invention relates to a solar battery module and a method of manufacturing a solar battery module.

2. Related Art

FIG. 5 shows a top view of a solar battery module of related art. FIG. 6 is an A-A cross sectional diagram of a solar battery module 170 shown in FIG. 5. The solar battery module of the related art will now be described with reference to FIGS. 5 and 6.

The solar battery module 170 is formed by forming a plurality of solar batteries 110 by sequentially layering a first electrode layer (transparent conductive film) 111, a semiconductor layer (photoelectric conversion layer) 112, and a second electrode layer (back side electrode) 114 over a light-transmissive substrate (transparent substrate) 101, and dividing the structure using a well-known laser patterning method. The plurality of solar batteries 110 formed in this manner are sealed between the light-transmissive substrate 101 and a protective member 155 by a sealing member (filler) 150, and a metal frame 165 is fixed to an end of the sealed solar battery 110 via a resin 160 (refer to JP 2008-85224 A). In FIG. 5, the sealing member 150 and the protective member 155 are not shown.

Such a solar battery 110 obtains generated electric power by extracting electron-hole pairs generated in the semiconductor layer 112 by light incident from a side of the light-transmissive substrate 101, using an internal electric field of the pn junction and on the sides of the first electrode layer 111 and the second electrode layer 114. Because of this, in order to increase the amount of light incident to the semiconductor layer 112, various improvements have been applied. For example, a configuration is employed in which the first electrode layer 111, an amorphous silicon layer having a p-i-n junction and functioning as the semiconductor layer 112, and the second electrode layer 114 are sequentially layered over the light-transmissive substrate 101, and an Ag electrode having a high reflectance in the effective wavelength region is used for the second electrode layer 114 so that the incident light is reflected between the second electrode layer 114 and the first electrode layer 111, to increase the amount of light reaching the semiconductor layer 112. In this configuration, the reflectivity of the second electrode layer 114 is increased so that the light of a long wavelength transmitting through the semiconductor layer 112 is effectively used, and short-circuiting current is improved. As described above, Ag is most commonly used for the second electrode layer 114 having a high reflectivity.

In the solar battery module 170 in which the metal frame 165 is attached by the resin 160 made of butyl rubber or the like at the end of the solar battery module 170 as described above, when the incident light incident on the substrate 101 or scattering light generated by scattering of the incident light by a contact surface between the substrate 101 and the solar battery 110 and in the solar battery 110 is incident on the ends of the solar battery module 170, most of the scattering light is absorbed by the resin 160, and it is not possible for the incident light to effectively contribute to the power generation.

The present invention has been conceived in view of the above-described circumstances, and an advantage of the present invention is that a method of manufacturing a solar battery module is provided in which the light incident on the end of the solar battery module is again incident to the solar battery so that the output current is increased.

### SUMMARY

According to one aspect of the present invention, there is provided a solar battery module comprising a light-transmissive substrate, a solar battery formed over a first surface of the light-transmissive substrate, and a first reflective section which is made of the same material as an electrode forming a part of the solar battery, which is provided over a second surface of the light-transmissive substrate, and which reflects light from the side of the substrate.

According to another aspect of the present invention, there is provided a solar battery module comprising a light-transmissive substrate, a solar battery formed over a first surface of the light-transmissive substrate, and a second reflective section which is made of the same material as an electrode forming a part of the solar battery, which is provided over a side end surface of the light-transmissive substrate, and which reflects light from the side of the substrate.

According to another aspect of the present invention, there is provided a method of manufacturing a solar battery module, comprising forming a first electrode layer over a first surface of a light-transmissive substrate, forming a semiconductor layer over the first electrode layer, forming a reflective conductive film over the semiconductor layer and over a second surface of the light-transmissive substrate using an inline sputtering device, and separating at least the first electrode layer or the reflective conductive film and forming one or a plurality of solar batteries, a second electrode, and a first reflective section, wherein in the forming of the reflective conductive film, a direction of transport of the light-transmissive substrate in the inline sputtering device differs from a direction of flow of current of the semiconductor layer.

According to another aspect of the present invention, there is provided a method of manufacturing a solar battery module, comprising forming a first electrode layer over a first surface of a light-transmissive substrate, forming a semiconductor layer over the first electrode layer, forming a reflective conductive film over the semiconductor layer and over a side end surface of the light-transmissive substrate using an inline sputtering device, and separating at least the first electrode layer or the reflective conductive film and forming one or a plurality of solar batteries, a second electrode, and a second reflective section, wherein in the forming of the reflective conductive film, a direction of transport of the light-transmissive substrate in the inline sputtering device differs from a direction of flow of current of the semiconductor layer.

According to another aspect of the present invention, there is provided a method of manufacturing a solar battery module, comprising forming a first electrode layer over a first surface of a light-transmissive substrate, forming a semiconductor layer over the first electrode layer, forming a reflective conductive film over the semiconductor layer and over a second surface of the light-transmissive substrate using an inline sputtering device, and separating at least the first electrode layer or the reflective conductive film and forming one or a plurality of solar batteries, a second electrode, and a first reflective section, wherein in the forming of the reflective conductive film, the light-transmissive substrate is transported in the inline sputtering device along a direction of flow of current of the semiconductor layer.

According to another aspect of the present invention, there is provided a method of manufacturing a solar battery module, comprising forming a first electrode layer over a first surface of a light-transmissive substrate, forming a semiconductor layer over the first electrode layer, forming a reflective conductive film over the semiconductor layer and over a side end surface of the light-transmissive substrate using an inline sputtering device, and separating at least the first electrode layer or the reflective conductive film and forming one or a plurality of solar batteries, a second electrode, and a second reflective section, wherein in the forming of the reflective conductive film, the light-transmissive substrate is transported in the inline sputtering device along a direction of flow of current of the semiconductor layer.

### BRIEF DESCRIPTION OF THE DRAWINGS

A preferred embodiment of the present invention will be described in further detail based on the following drawings, wherein:

FIG. 1 is a top view of a solar battery module according to a preferred embodiment of the present invention;

FIG. 2 is an enlarged cross sectional diagram at an end of a solar battery module according to a preferred embodiment shown in FIG. 1;

FIG. 3 is an enlarged cross sectional diagram of an end of a solar battery module for explaining a manufacturing process of a solar battery module according to a preferred embodiment of the present invention;

FIG. 4 is a schematic diagram showing a structure of a manufacturing device of a solar battery module which is used in a manufacturing process of a solar battery module according to a preferred embodiment of the present invention;

FIG. 5 is a top view of a solar battery module in related art; and

FIG. 6 is a cross sectional diagram at an end of a solar battery module in related art.

### DETAILED DESCRIPTION

A preferred embodiment of the present invention will now be described with reference to the drawings. In the description of the drawings, same or similar reference numerals are assigned to the same or similar sections. It should be understood, however, that the drawings are schematic and the ratio or the like of the sizes differ from actual size or the like. Thus, the specific size or the like should be determined based on the following description. In addition, it should also be understood that the relationship or ratio of sizes among the drawings may differ from each other.

### (Structure of Solar Battery Module)

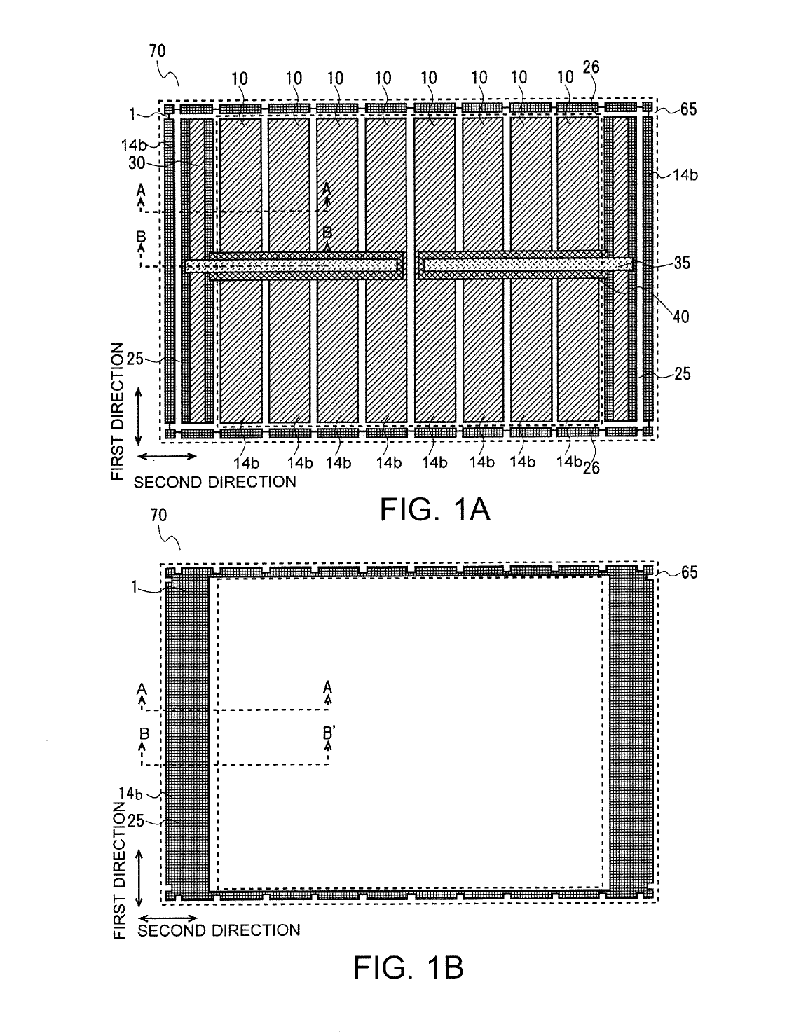

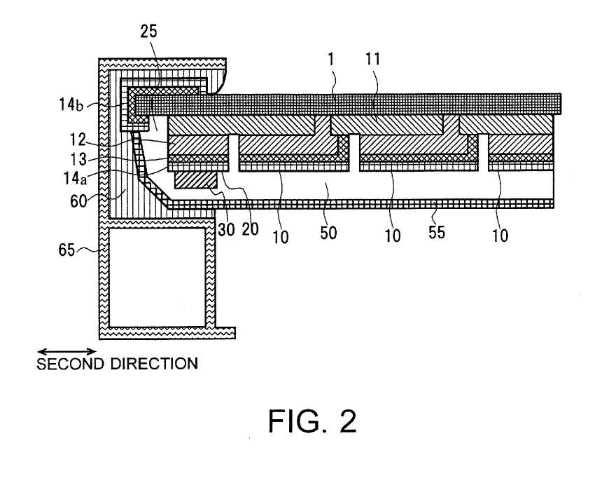

A solar battery 70 and a manufacturing method thereof in a preferred embodiment of the present invention will now be described with reference to the drawings. As top views of the solar battery module 70 manufactured in the preferred embodiment of the present invention, a top view from a back surface side is shown in FIG. 1A, and a top view of a light-receiving surface side is shown in FIG. 1B. FIG. 2 is an enlarged cross sectional diagram of the solar battery module 70 shown in FIG. 1. More specifically, FIG. 2 is an enlarged cross sectional diagram corresponding to the A-A cross section of the solar battery module 70 shown in FIG. 1.

A structure of the solar battery module 70 in the present embodiment will now be described with reference to FIGS. 1 and 2. In FIG. 1, a sealing member 50 and a protective member 55 are not shown.

The solar battery module 70 comprises a substrate 1, a plurality of solar batteries 10, an extracting electrode 20, an extracting line member 30, an output line member 35, an insulating film 40, a sealing member 50, and a protective member 55.

The substrate 1 is a single substrate for forming the plurality of solar batteries 10 and the extracting electrode 20. For the substrate 1, glass, plastic, etc. which is insulating may be used.

The plurality of solar batteries 10 are formed along a first direction over the substrate 1. The plurality of solar batteries 10 are arranged in parallel along a second direction which is approximately perpendicular to the first direction, and are electrically connected in series with each other.

The solar battery 10 comprises a first electrode layer 11, a semiconductor layer 12, a transparent conductive film 13, and a second electrode layer 14a. The first electrode layer 11, the semiconductor layer 12, the transparent conductive film 13, and the second electrode layer 14a are sequentially layered over the substrate 1 while being subjected to well-known laser patterning.

The first electrode layer 11 is formed over a primary surface of the substrate 1, and is conductive and light-transmissive. For the first electrode layer 11, in the present embodiment, ZnO which has a high light transmittance, a low resistivity, and plasticity, and which is inexpensive, is used.

The semiconductor layer 12 generates charges (electrons and holes) by incident light from the side of the first electrode layer. For the semiconductor layer 12, for example, a single layer or a layered structure of an amorphous silicon semiconductor layer or a microcrystalline silicon semiconductor layer having a basic structure of a pin junction or a pn junction may be used. The semiconductor layer 12 of the present embodiment comprises two photoelectric conversion units, and comprises an amorphous silicon semiconductor and a microcrystalline silicon semiconductor layered from the side of the first electrode layer 11 in this order. In this specification, the term “microcrystalline” refers not only to a complete crystal state, but also a state where an amorphous state is partially included.

The transparent conductive film 13 is formed over at least the semiconductor layer 12, and is formed covering a side end section of the substrate 1 and both end surfaces of the light-receiving surface side of the substrate 1. With the transparent conductive film 13, it is possible to prevent alloying of the semiconductor layer 12 and the second electrode layer 14a, and to reduce a connection resistance between the semiconductor layer 12 and the second electrode layer 14a.

The second electrode layer 14a is formed over the transparent conductive film 13. The transparent conductive film 13 and the second electrode layer 14a of one solar battery 10 contact the first electrode layer 11 of another solar battery 10 which is adjacent to the one solar battery 10. In this manner, the one solar battery 10 and the other solar battery 10 are electrically connected in series.

In addition, the second electrode layer 14a is formed covering the side end and both end surfaces of the substrate 1, and forms a reflective section 14b by these sections. In the present embodiment, a Ag film having a high reflectivity and having a thickness of 200 nm is used as the second electrode layer 14a.

The extracting electrode 20 extracts charges generated by the plurality of solar batteries 10. The extracting electrode 20 comprises, similar to the solar battery 10, the first electrode layer 11, the semiconductor layer 12, and the second electrode layer 14a. The first electrode layer 11, the semiconductor layer 12, the second electrode layer 14a, and the reflective section 14b are sequentially layered over the substrate 1 while being subjected to the well-known laser patterning. The extracting electrode 20 is formed over the substrate 1 along the first direction.

The extracting line member 30 extracts charges from the extracting electrode 20. More specifically, the extracting line member 30 has a function as a collecting electrode which collects charges from the extracting electrode 20.

The extracting line member 30 comprises a conductive base member and solder plated over an outer periphery of the base member. The extracting line member 30 is connected with solder over the extracting electrode 20 along the extracting electrode 20 (along the first direction). As the base member, copper which is formed in a thin plate shape, a line shape, or a twisted line shape may be used. Alternatively, the extracting line member 30 may be partially connected with solder to the extracting electrode 20 at a plurality of locations.

The output line member 35 guides the charges collected by the extracting line member 30 to the outside of the solar battery module 70. The output line member 35 has a structure similar to the extracting line member 30, and one end of the output line member 35 is connected with solder over the extracting line member 30. In this structure, the insulating film 40 is placed between the output line member 35 and the plurality of solar batteries 10, and the output line member 35 and the plurality of solar batteries 10 are insulated from each other.

The sealing member 50 seals the plurality of solar batteries 10, the extracting electrode 20, and the extracting line member 30 between the substrate 1 and the protective member 55, and is placed to absorb a shock applied to the solar battery 10. In the present embodiment, EVA is used for the sealing member 50.

The protective member 55 is placed over the sealing member 50. In the present embodiment, a layered structure of PET/Al film/PET is used as the protective member 55.

An end of the output line member 35 which is not connected to the power extracting line 30 extends from an opening formed in the sealing member 50 and the protective member 55, and is connected to a terminal box (not shown).

A frame 65 made of Al, SUS, or iron is attached by the resin 60 which is made of butyl rubber or the like and which has an insulating characteristic and weather resistance to an end of the plurality of the sealed solar batteries 10, to complete the solar battery module 70.

In the present embodiment, a photoelectric conversion unit in which an amorphous silicon semiconductor and a microcrystalline silicon semiconductor are sequentially layered is used, but the present invention is not limited to such a configuration, and similar advantages may be obtained using a photoelectric conversion unit in which a single layer, or a layered structure of three or more layers, of microcrystalline or amorphous layers, are layered.

Alternatively, an intermediate layer comprising ZnO, SnO₂, SiO₂, or MgZnO may be provided between the photoelectric conversion units, and the optical characteristic may be improved.

The first electrode layer 11 may alternatively be formed with one or a layered structure of a plurality of metal oxides selected from SnO₂, In₂O₃, TiO₂, and Zn₂SnO₄, in place of ZnO which is used in the present embodiment. Alternatively, the metal oxides may be doped with F, Sn, Al, Ga, and Nb.

In the present embodiment, after the transparent conductive film 13 comprising ZnO is formed, a single layer of Ag is formed as the second electrode layer 14a. Alternatively, it is also possible to sequentially form, for example, over the semiconductor layer 12, one or a plurality of layers of metal oxides such as In₂O₃, SnO₂, TiO₂, and Zn₂SnO₄ as the transparent conductive film 13, and one or a plurality of layers of metal films such as Al, Ti, and Ni as the second electrode layer 14a. In addition, the structure may be a structure having at least one layer of the second electrode layer 14a, and a structure having no transparent conductive film may be employed.

As the sealing member 50, in place of EVA, an ethylene-based resin such as EEA, PVB, silicone, urethane, acryl, and an epoxy resin may be used.

As the protective member 55, in place of the layered structure of PET/Al film/PET, it is also possible to use a single layer of resin such as fluorine-based resin (such as ETFE, PVDF, PCTFE), PC, PET, PEN, PVF, and acryl or a structure sandwiching a metal film, a steel plate such as SUS and Galvalume, and glass.

The reflective section 14b which is a characteristic section of the present embodiment will now be described in detail with reference to FIGS. 1 and 2.

In the solar battery module 70 of the present embodiment, the reflective section 14b is formed to extend and wrap-around to the light-receiving surface side when the second electrode layer 14a is formed on the back side of the substrate 1, and covers the side end and both side surfaces of the substrate 1. The wrapped-around reflective section 14b covers, on the light-receiving surface, a non-effective region which does not contribute to the power generation, and covers the solar battery 10 positioned at the end of the substrate 1. With such a structure, the light incident on the substrate 1 can be effectively used for power generation without reducing the amount of light incident on the semiconductor layer 12 of the solar battery 10. In other words, the incident light which is directly incident on the end in which the solar battery 10 or the extracting electrode 20 is not formed, and light which is scattered at interfaces between the substrate 1 and the first electrode layer 11, between the semiconductor layer 12 and the second electrode layer 14a, or between the first electrode layer 11 and the semiconductor layer 12 and incident on the reflective section 14b can be reflected again by the reflective section 14b, and be incident on the semiconductor layer 12. The light reflected by the reflective section 14b causes electron-hole pairs to be generated in the semiconductor layer 12 and a photocurrent to be generated by an internal electric field of the pn junction. In other words, by increasing the amount of incident light to the semiconductor layer 12, the reflective section 14b contributes to an increase of a short-circuiting current of the solar battery module 70. Alternatively, a configuration may be employed in which the transparent conductive film 13 is provided between the reflective section 14b covering the side end of the substrate 1 and the substrate 1, and advantages similar to those obtained without the transparent conductive film 13 may be obtained.

In addition, a first separation channel 25 for separating the extracting electrode 20 and the reflective section 14b is formed on a back surface side of the solar battery module 70, and insulation at the end of the substrate 1 is secured. In addition, in order to prevent short-circuiting of the extracting electrode 20 and the plurality of solar batteries 10 via the reflective section 14b, a second separation channel 26 is formed, and the extracting electrode 20 and the plurality of solar batteries 10 are separated from the reflective section 14b. Therefore, insulation from the outside can be secured for the plurality of solar batteries 10 of the present embodiment.

Further, in the solar battery module 70, the resin 60 is placed to cover the formed reflective section 14b, and the frame 65 is attached. The resin 60 is placed between the frame 65 made of a metal and the solar battery module 70, and acts as a shock-absorbing member to protect the solar battery module 70 from a shock applied from the outside. Moreover, with the use of the insulating resin 60, the insulation from the outside can be more reliably secured.

At the end of the reflective section 14b positioned over the light-receiving surface of the substrate 1, it is preferable to form the structure such that the transparent conductive film 13 covers the end of the reflective section 14b and the end of the transparent conductive film 13 is not exposed. With this configuration, the reflective section 14b prevents intrusion of moisture to the transparent conductive film 13, and prevents reduction of the light transmittance. Therefore, the light incident on the reflective unit 14b can be more reliably reflected, and be incident on the solar battery 10.

As described, with the present invention, the light incident on the substrate 1 from the light-receiving surface is also reflected at the end of the solar battery module 70 and is incident again to the semiconductor layer 12, so that the amount of light incident on the semiconductor layer 12 can be increased and the short-circuiting current can be increased. In addition, the reliability of the solar battery module 70 can be improved.

### (Manufacturing Method of Solar Battery Module)

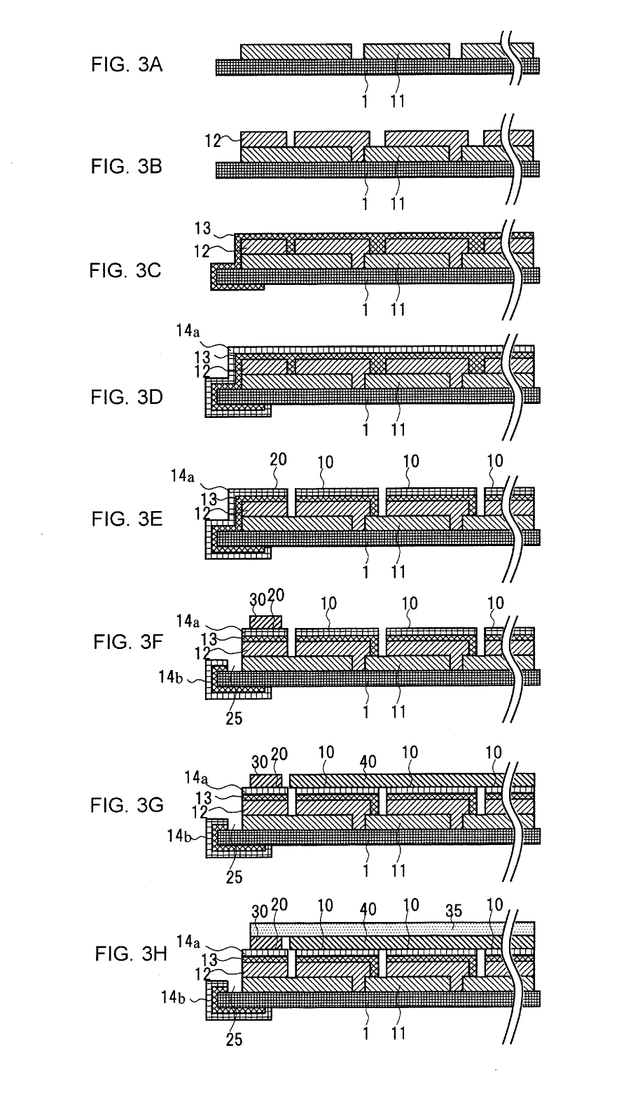

Next, a method of manufacturing the solar battery module 70 according to the present embodiment will be described with reference to FIGS. 1, 2, and 3. FIG. 3 is an enlarged cross sectional diagram showing a manufacturing process at a section corresponding to B-B of the solar battery module 70 shown in FIG. 1A.

First, as shown in FIG. 3A, the first electrode layer 11 having a thickness of 600 nm and comprising ZnO is formed through sputtering over the light-transmissive substrate 1 having a thickness of 4 mm and comprising glass. Then, YAG laser is irradiated from the side of the first electrode layer 11 of the light-transmissive substrate 1, to pattern the first electrode layer 11 into a strip shape. For this laser separation machining, Nd:YAG laser is used having a wavelength of approximately 1.06 μm, an energy density of 13 J/cm³, and a pulse frequency of 3 kHz.

Next, as shown in FIG. 3B, the semiconductor layer 12 is formed with a plasma processing device.

For the semiconductor layer 12, a p-type amorphous silicon semiconductor layer having a thickness of 10 nm is formed using mixture gas of SiH₄, CH₄, H₂, and B₂H₆ as material gas, an i-type amorphous silicon semiconductor layer having a thickness of 300 nm is formed using mixture gas of SiH₄ and H₂ as material gas, and an n-type amorphous silicon semiconductor layer having a thickness of 20 nm is formed using mixture gas of SiH₄, H₂, and PH₄ as material gas, while these layers are sequentially layered. Then, a p-type microcrystalline silicon semiconductor layer having a thickness of 10 nm is formed using mixture gas of SiH₄, H₂, and B₂H₆ as material gas, an i-type microcrystalline silicon semiconductor layer having a thickness of 2000 nm is formed using mixture gas of SiH₄ and H₂ as material gas, and an n-type microcrystalline silicon semiconductor layer having a thickness of 20 nm is formed using mixture gas of SiH₄, H₂, and PH₄ as material gas, while these layers are sequentially layered. Table 1 shows details of conditions of the plasma processing device.

TABLE 1

| | | SUBSTRATE | GAS FLOW | REACTION | RF | FILM |
|---|---|---|---|---|---|---|
| | | TEMPERATURE | RATE | PRESSURE | POWER | THICKNESS |
| | LAYER | (C. °) | (sccm) | (Pa) | (W) | (nm) |
| AMORPHOUS Si | p | 180 | SiH₄: 300 | 106 | 100 | 10 |
| SEMICONDUCTOR | LAYER | | CH₄: 300 | | | |
| LAYER | | | H₂: 2000 | | | |
| | | | B₂H₆: 3 | | | |
| | i | 200 | SiH₄: 300 | 106 | 200 | 300 |
| | LAYER | | H₂: 2000 | | | |
| | n | 180 | SiH₄: 300 | 133 | 200 | 20 |
| | LAYER | | H₂: 2000 | | | |
| | | | PH₄: 5 | | | |
| MICROCRYSTALLINE | p | 180 | SiH₄: 10 | 106 | 1000 | 10 |
| Si SEMICONDUCTOR | LAYER | | H₂: 2000 | | | |
| LAYER | | | B₂H₆: 3 | | | |
| | i | 200 | SiH₄: 100 | 133 | 2000 | 3000 |
| | LAYER | | H₂: 2000 | | | |
| | n | 180 | SiH₄: 10 | 133 | 2000 | 20 |
| | LAYER | | H₂: 2000 | | | |
| | | | PH₄: 5 | | | |

YAG laser is irradiated from the side of the first electrode layer 11 to a region beside the patterning position of the layered structure of the semiconductor layer 12 and the first electrode layer 11 so that the semiconductor layer 12 formed on the back surface side of the substrate 1 is separated and removed, and patterned in the strip shape. For this laser separation machining, Nd:YAG laser is used having an energy density of 0.7 J/cm³ and a pulse frequency of 3 kHz.

Next, as shown in FIG. 3C, the transparent conductive film 13 comprising ZnO is formed over the semiconductor layer 12 through sputtering. The transparent conductive film 13 is formed through a method similar to the second electrode layer 14a such that the transparent conductive film 13 is formed wrapped-around in the region where the semiconductor layer 12 is removed by the patterning, and at the side end and both end surfaces of the substrate 1.

As shown in FIG. 3D, a Ag film having a thickness of 200 nm is formed over the transparent conductive film 13 through sputtering, to form the second electrode layer 14a. The Ag film is formed such that the second electrode layer 14a is wrapped-around in the region in which the semiconductor layer 12 is removed by the patterning, and at the ends of the light-receiving surface including the end of the substrate 1, as will be described later. In this process, the end of the transparent conductive film 13 positioned on the light-receiving surface side is formed to be covered by the reflective film 14b.

As shown in FIG. 3E, YAG laser is irradiated from the back surface side to a region beside the patterning position of the semiconductor layer 12, to separate the semiconductor layer 12, the transparent conductive film 13, and the second electrode layer 14a, and pattern these layers in a strip shape. For this laser separation machining, Nd:YAG laser is used having an energy density of 0.7 J/cm³, and a pulse frequency of 4 kHz.

As shown in FIG. 3F, in the wrapped-around sections of the transparent conductive film 13 and the second electrode layer 14a, a first separation channel 25 extending in the second direction for separating these sections from the solar battery 10 and the extracting electrode 20 is formed with laser. Similarly, a second separation channel 26 extending in the first direction shown in FIG. 1 is formed with laser, and the section is separated from the extracting electrode 20. For this laser separation machining, Nd:YAG laser is used having a wavelength of approximately 1.06 μm, an energy density of 13 J/cm³, and a pulse frequency of 3 kHz. Each of the first separation channel 25 and the second separation channel 26 preferably has a width of greater than or equal to 1 mm for effective insulation.

With such a process, the plurality of solar batteries 10 which are connected in series with each other, the extracting electrode 20, and the reflective section 14b are formed over the substrate 1.

As shown in FIG. 3G, the extracting line member 30 is placed over the extracting electrode 20 and is connected with solder to the extracting electrode 20.

As shown in FIG. 3H, the insulating film 40 is placed over the plurality of solar batteries 10, the output line member 35 is placed over the insulating film 40, and one end of the output line member 35 is connected to the extracting line member 30.

As shown in FIG. 2, the sealing member 50 comprising EVA and the protective member 55 comprising PET/Al film/PET are provided over the second electrode layer 14a and the extracting line member 30 of the solar battery 10. In this process, one end of the output line member 35 which is not connected to the electric power extracting line 30 is brought out from the opening formed in the sealing member 50 and the protective member 55. The terminal box (not shown) is connected to the end of the output line member 35 extending from the opening.

A shock-absorbing member comprising the resin 60 formed with butyl rubber or the like is provided over the end of the plurality of the sealed solar batteries 10 as shown in FIG. 2, the frame 65 comprising Al is provided, and the solar battery module 70 is completed.

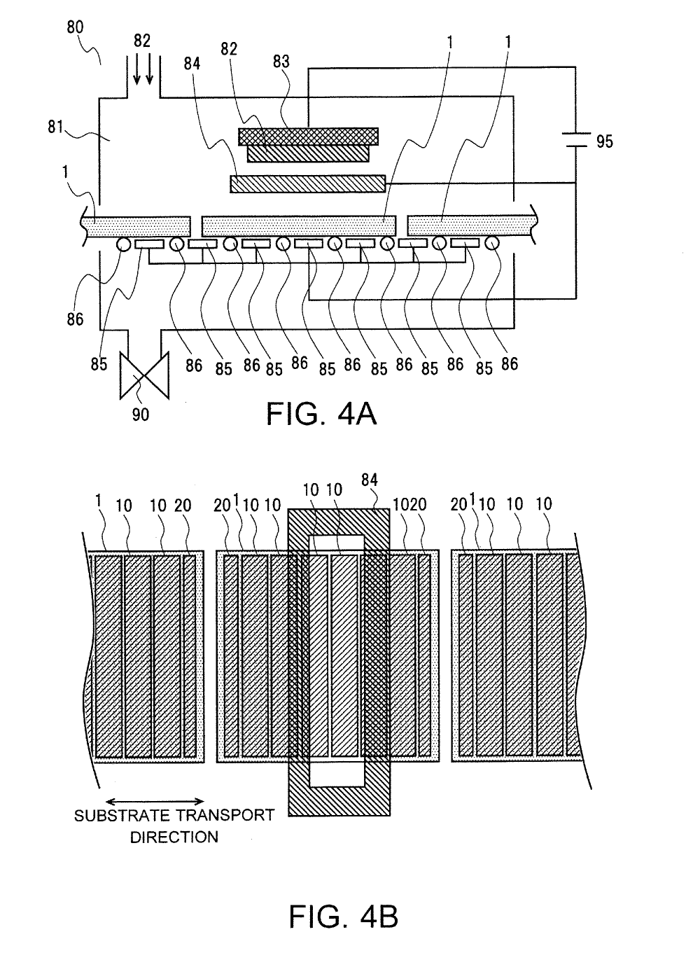

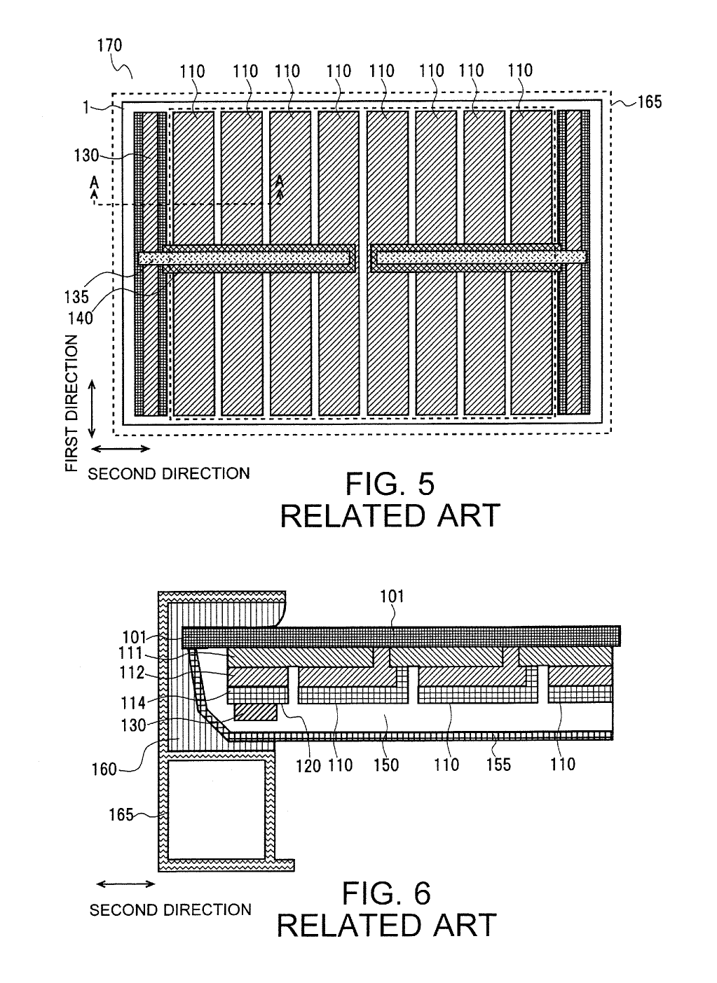

In the following, a sputtering method of the second electrode layer 14a which is a characteristic of the present invention will be described in detail with reference to FIG. 4. FIG. 4 is a schematic diagram of an inline sputtering device 80 which continuously transports a plurality of substrates and sequentially applies the sputtering process. FIG. 4A is a schematic diagram showing a structure of the inline sputtering device 80, and FIG. 4B is a top view showing the transporting of the substrate 1 in a reaction chamber 81. In FIG. 4B, a target 82 comprising Ag, a support section 83 which supports the target 82, an electrode 85 provided below the substrate 1, and a roller 86 which transports the substrate 1 are not shown.

The second electrode layer 14a is formed by the inline sputtering device 80 shown in FIG. 4. In the present embodiment, first, a structure is prepared in which the first electrode layer 11 and the semiconductor layer 12 are sequentially layered over the light-transmissive substrate 1. Then, the substrate 1 in which structures up to the semiconductor layer 12 are formed is placed in the reaction chamber 81 of the inline sputtering device 80 shown in FIG. 4A, heated to a temperature of 60° C.˜120° C. when the second electrode layer 14a is formed, and transported. The reaction chamber 81 is vacuumed with a vacuum pump 90 to a pressure of approximately 1.0×10⁻⁵ Pa, argon gas (hereinafter simply referred to as Ar) and oxygen (hereinafter simply referred to as O₂) are introduced from an air intake 82, and the internal pressure is maintained at a pressure of 0.4 Pa˜0.7 Pa. The target 82 comprising Ag is fixed on the support section 83, a cathode of a power supply device 95 is connected to the support section 83, an anode of the power supply device is connected to a deposition prevention plate 84 and the electrode 85 provided below the substrate 1, the substrate 1 is moved while a discharge process at a DC power density of 0.9 W/cm²˜4.0 W/cm² is applied, the target 82 is sputtered, and the second electrode layer 14a comprising Ag is continuously formed over the semiconductor layer 12.

In the present embodiment, the deposition prevention plate 84 is placed between the target 82 and the substrate 1, and the Ag film is formed over the substrate 1 through the opening of the deposition prevention plate 84. The opening of the deposition prevention plate 84 is formed in a larger size than a length of the substrate 1 in a direction approximately perpendicular to the transporting direction of the substrate, and is formed such that the formed film can be more easily wrapped-around to the ends in the first direction of the substrate 1.

In the solar battery module 70 shown in FIG. 1A, while a photocurrent can be generated by incidence of light on the semiconductor layer 12 of the solar battery 10, the light incident on the extracting electrode 20 cannot contribute to the power generation. Because of this, when the reflective section 14b is formed over the end, formation of a reflective section 14b with a superior characteristic on a side extending in the second direction where the ends of the plurality of solar batteries 10 formed over the substrate 1 are adjacent to each other, instead of the side extending in the first direction where the extracting electrodes 20 of the substrate 1 are adjacent to each other, results in a greater contribution of the incident light to the power generation.

In the present embodiment, the reflective conductive film is formed using only inert gas such as Ar for driving out the molecules of the target comprising Ag which is a reflective conductive material. However, when the transparent conductive film 13 comprising a metal oxide is formed through sputtering, O₂ which is introduced in order to stably form the transparent conductive film 13 may be introduced into the processing chamber 81 for forming the second electrode layer 14a, which may result in blackening of the reflective conductive film comprising Ag and reduction in the reflectivity.

In the inline sputtering device 80, while the substrate 1 is transported by the roller 86, the Ag film is formed over the substrate 1. During the film formation in the inline sputtering device 80, in order to improve the throughput, the substrates 10 are transported with a narrow spacing. Therefore, the distance between the substrate 1 and the wall surface of the reaction chamber 81 is greater compared to the distance between the substrate 1 and the adjacent substrate 1. Because of this structure, the region between the substrate 1 and the adjacent substrate 1 has a higher degree of vacuum than the region between the substrate 1 and the wall surface of the reaction chamber 81. Therefore, when the reflective conductive film is formed in the inline sputtering device 80, O₂ existing between the substrate 1 and the adjacent substrate 1 can be removed to a higher degree. In other words, on the side where the substrates 1 are adjacent to each other, the reflective conductive film comprising a metal does not tend to become an oxide, and the reflective conductive film with a high reflectivity can be formed.

For this purpose, in the present embodiment, in order to form the reflective section 14b with preferable conditions on a side extending in the second direction where the ends of the plurality of solar batteries 10 are adjacent to each other, the Ag film is formed such that the transport direction of the substrate 1 and the first direction where the ends of the plurality of solar batteries 10 formed over the substrate are adjacent to each other are approximately the same direction. That is, the substrate is transported in a direction approximately equal to the direction of the side of the first direction where the solar batteries 10 extend, so that the reflective section of a high reflectivity can be formed on a side of the second direction where the ends of the solar batteries 10 are adjacent to each other. In addition, because the reflective section 14b is provided on the side extending in the second direction where the ends of the plurality of solar batteries 10 are adjacent to each other, more light can be reflected and made incident on the solar battery 10. With such a configuration, the photocurrent generated in the individual solar battery 10 can be increased, and a higher output can be obtained as the solar battery module 70.

In addition, in the inline sputtering device 80, while the substrate 1 is transported by the roller 86, the Ag film is formed over the substrate 1. Because of this, when a side which is approximately parallel to the direction of transport of the substrate 1 and the side which is approximately perpendicular to the substrate transport direction are compared, while the reflective section 14b in which the Ag film is uniformly wrapped-around can be easily formed on the side which is approximately parallel to the transport direction, the Ag film is not easily uniformly wrapped-around on the side which is approximately perpendicular to the transport direction and it is difficult to control the reflective section 14b to a preferable thickness.

Because of this, by transporting the substrate in a direction approximately the same as the side extending in the second direction where the ends of the plurality of solar batteries 10 are adjacent, it is possible to form a reflective section with a uniform thickness. In addition, because the reflective section 14b is provided on the side extending in the second direction where the ends of the plurality of solar batteries 10 are adjacent, more light can be reflected and made incident on the solar battery 10. Because of this structure, the photocurrent generated in the individual solar battery 10 can be increased and a higher output can be obtained as the solar battery module 70.

In cases other than the configuration of the present embodiment where a single layer of ZnO is formed as the transparent conductive film 13 and a single layer of Ag is formed as the second electrode layer 14a, similar to the configuration of the present embodiment, the transparent conductive film 13 and the second electrode layer 14a can be formed by setting, as the target 82, a metal oxide such as In₂O₃, SnO₂, TiO₂, Zn₂SnO₄, or the like and a metal such as Al, Ti, Ni, or the like in place of ZnO and Ag which are used in the present embodiment, and sputtering the metal oxide and metal. Alternatively, the transparent conductive film 13 and the second electrode layer 14a each having a plurality of layers may be formed using a plurality of similar devices or repeatedly sputtering while changing the target 82.

In addition, although a direct current (DC) sputtering device is used as the inline sputtering device 80 in the present embodiment, the present invention is not limited to such a configuration, and alternatively, high frequency sputtering, magnetron sputtering, etc. may be applied.

Moreover, in the transparent conductive film 13 and the second electrode layer 14a which are wrapped around, the first separation channel 25 extending in the second direction and having a width of 1 mm is formed with laser for separating the transparent conductive film 13 and the second electrode layer 14a from the solar battery 10 in which the first electrode layer 11, the semiconductor layer 12, the transparent conductive film 13, and the second electrode layer 14a are layered and the extracting electrode 20. Similarly, the second separation channel 26 extending in the first direction and having a width of 1 mm as shown in FIG. 1 is formed with laser for separation from the extracting electrode 20. With this structure, when the solar battery 10 is sealed by the protective member 55 with the sealing member 50 therebetween, insulation from the outside of the solar battery 10 can be secured and the reliability can be improved.

As described, with the manufacturing method of the solar battery module according to the present invention, because the light incident from the light-receiving surface to the substrate 1 is reflected by the reflective section 14b and incident again to the semiconductor layer 12, the short-circuiting current can be increased and the insulation between the solar battery module 70 and the outside can be secured, and thus, the reliability can be improved. In other words, with the manufacturing method of the solar battery of the present invention, improvement in output of the solar battery module and the prevention of reduction of the reliability of the solar battery can be simultaneously achieved.

What is claimed is:

1. A solar battery module, comprising:
a light-transmissive substrate;
a solar battery formed over a first surface of the light-transmissive substrate; and
a first reflective section which is made of the same material as an electrode forming a part of the solar battery, which is provided over a second surface of the light-transmissive substrate, and which reflects light from the side of the substrate.

2. The solar battery module according to claim 1, further comprising:
a second reflective section which is made of the same material as an electrode forming a part of the solar battery, which is provided over a side end surface of the light-transmissive substrate, and which reflects light from the side of the substrate.

3. The solar battery module according to claim 1, wherein
a light-transmissive conductive film exists between the first reflective section and the light-transmissive substrate.

4. The solar battery module according to claim 3, wherein
the first reflective section covers an end of the light-transmissive conductive film over the second surface of the light-transmissive substrate.

5. The solar battery module according to claim 1, wherein
the first reflective section extends and wraps around the side of the first surface of the light-transmissive substrate.

6. The solar battery module according to claim 1, wherein
the first reflective section is formed on an end in a direction different from a direction of flow of current in the solar battery formed over the light-transmissive substrate.

7. A method of manufacturing a solar battery module, comprising:
forming a first electrode layer over a first surface of a light-transmissive substrate;
forming a semiconductor layer over the first electrode layer;
forming a reflective conductive film over the semiconductor layer and over a second surface of the light-transmissive substrate using an inline sputtering device, and
separating at least the first electrode layer or the reflective conductive film and forming one or a plurality of solar batteries, a second electrode, and a first reflective section, wherein
in the forming of the reflective conductive film, a direction of transport of the light-transmissive substrate in the inline sputtering device differs from a direction of flow of current of the semiconductor layer.

8. The method of manufacturing the solar battery module according to claim 7, wherein
the reflective conductive film is further formed over a side end surface of the light-transmissive substrate using the inline sputtering device.

9. The method of manufacturing the solar battery module according to claim 7, wherein
a light-transmissive conductive film exists between the first reflective section and the light-transmissive substrate.

10. The method of manufacturing the solar battery module according to claim 9, wherein
the first reflective section covers an end of the light-transmissive conductive film over the second surface of the light-transmissive substrate.

11. A method of manufacturing a solar battery module, comprising:
forming a first electrode layer over a first surface of a light-transmissive substrate;
forming a semiconductor layer over the first electrode layer;
forming a reflective conductive film over the semiconductor layer and over a second surface of the light-transmissive substrate using an inline sputtering device; and
separating at least the first electrode layer or the reflective conductive film and forming one or a plurality of solar batteries, a second electrode, and a first reflective section, wherein
in the forming of the reflective conductive film, the light-transmissive substrate is transported in the inline sputtering device along a direction of flow of current of the semiconductor layer.

12. The method of manufacturing the solar battery module according claim 11, wherein
the reflective conductive film is formed over a side end surface of the light-transmissive substrate using the inline sputtering device.

13. The method of manufacturing the solar battery module according to claim 11, wherein
a light-transmissive conductive film exists between the first reflective section and the light-transmissive substrate.

14. The method of manufacturing the solar battery module according to claim 13, wherein
the first reflective section covers an end of the light-transmissive conductive film over the second surface of the light-transmissive substrate.
